(19) United States
(12) Patent Application Publication
(10) Pub. No.: US 2021/0320102 A1
(43) Pub. Date: Oct. 14, 2021

(54) PASSIVE TUNABLE INTEGRATED CIRCUIT WITH ELECTRO-STATIC DISCHARGE PROTECTION

(71) Applicant: SEMICONDUCTOR COMPONENTS INDUSTRIES, LLC, Phoenix, AZ (US)

(72) Inventor: Gareth Pryce WEALE, New Hamburg (CA)

(73) Assignee: SEMICONDUCTOR COMPONENTS INDUSTRIES, LLC, Phoenix, AZ (US)

(21) Appl. No.: 16/844,102

(22) Filed: Apr. 9, 2020

(51) Int. Cl. H01L 27/02; H01L 27/08; H01L 29/93; H01L 29/66; H01L 23/66

(52) U.S. Cl. CPC H01L 27/0288; H01L 27/0808; H01L 2223/6655; H01L 29/66174; H01L 23/66; H01L 29/93

(57) ABSTRACT

A passive tunable integrated circuit (PTIC) having an electro-static discharge (ESD) protection circuit is disclosed. The ESD protection circuit includes at least one spark gap that has a breakdown voltage determined by design parameters. The at least one spark gaps are configured to route signals above a breakdown voltage to ground in order to protect a variable capacitor. The design parameters can be based on a material (Barium Strontium Titanate), a structure, and a fabrication process of the PTIC and further based on expected ESD signals for a mobile device application.

### FIELD OF THE DISCLOSURE

The present disclosure relates to radio frequency (RF) components and more specifically to an RF integrated circuit (IC) having electro-static discharge (ESD) protection.

### BACKGROUND

Many RF applications require adaptive tuning (e.g., matching) to provide operation over a range of uses and environments. For example, a tunable capacitance can enable an antenna of a mobile phone to operate properly (e.g., efficiently) over multiple frequencies (e.g., different bands) and operate in a variety of environments (e.g., handheld). A capacitor can include a pair of electrodes (i.e., plates) that each have an area (A) and that are separated by a distance (d). A volume is formed between the electrodes that can be filled with insulating material having a dielectric constant (c). Tuning the capacitor can include changing any of these parameters (A, d, c), but a capacitor that can be tuned by changing the dielectric constant (i.e., relative permittivity) of the insulating material may offer advantages in size and simplicity. The tunable dielectric capacitor can be implemented as an integrated circuit, which is well suited for mobile electronics. It is in this context that implementations of the disclosure arise.

### SUMMARY

In at least one aspect, the present disclosure generally describes a passive tunable integrated circuit. The passive tunable integrated circuit includes a variable capacitor that includes a capacitor array that is coupled between an input electrode and an output electrode. At least one capacitor in the capacitor array has a tunable dielectric coupled to a radio-frequency ground electrode. The passive tunable integrated circuit further includes and input electro-static discharge protection circuit that is coupled between the input electrode and the radio-frequency ground electrode. The input electro-static discharge protection circuit includes at least one spark gap.

In another aspect, the present disclosure generally describes a radio frequency tuner for a mobile device. The radio frequency tuner includes a passive tunable integrated circuit that includes an input and/or output electro-static discharge protection circuit. The electro-static discharge protection circuit is coupled between an input and/or output electrode and a radio-frequency ground electrode. The input and/or output electro-static discharge protection circuit includes at least one spark gap that is configured to couple an electro-static discharge above a trigger field strength to the radio-frequency ground electrode.

In another aspect, the present disclosure generally describes a method to protect a passive tunable integrated circuit from an electro-static discharge. The method includes fabricating a variable capacitor that includes a tunable dielectric material. The method further includes depositing a first metal layer on the variable capacitor, which defines an input electrode, an output electrode, a radio-frequency ground electrode, and at least one spark gap that is coupled between the input electrode and the radio-frequency ground electrode. The method further includes depositing an overcoat on at least a portion the first metal layer. The at least one spark gap of the first metal layer has no overcoat to lower a breakdown voltage of the at least one spark gap to below a breakdown voltage of the variable capacitor so than an electro-static discharge having a voltage that can damage the radio-frequency variable capacitor is routed to the radio-frequency ground electrode.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 schematically illustrates a block diagram of a mobile device according to an implementation of the present disclosure.

FIG. 2 schematically illustrates a block diagram of a possible implementation of an RF tuner including a variable capacitor.

FIG. 3 schematically illustrates a block diagram of a passive tunable integrated circuit (PTIC) including a variable capacitor with ESD protection according to a possible implementation of the present disclosure.

FIG. 4 is a top view of a variable capacitor according to a possible implementation of the present disclosure.

FIGS. 5A, 5B, 5C, and 5D illustrate possible implementations of an ESD protection circuits that include at least one spark gap.

FIG. 6 is a side view of a portion of a spark gap for an ESD protection circuit of a PTIC according to a possible implementation of the present disclosure.

FIG. 7 is a top view of a PTIC including ESD protection according to a possible implementation of the present disclosure.

FIG. 8 is a flowchart of a method to protect a PTIC from an ESD.

The components in the drawings are not necessarily to scale relative to each other. Like reference numerals designate corresponding parts throughout the several views.

### DETAILED DESCRIPTION

A wireless device may have an analog RF front-end circuit (i.e., RF front-end) configured just before/after a transmit/receive (T/R) antenna. The RF front-end may be configured to match impedances between the antenna and other circuitry (e.g., RF amplifiers). Because an antenna may be easily loaded (e.g., through capacitive coupling) by an environment, its impedance may not be constant. Accordingly, the RF front-end may require a tuning circuit that can tune the impedance of the antenna to the internal circuitry (and vice versa). In some implementations, the tuning circuit can automatically respond to changes in an environment of the antenna. This, so called, auto-tuning can optimize power efficiency and signal levels to extend battery life and improve performance (e.g., data rate) of a wireless device.

Tuning may be carried out by switching various impedance combinations to find a reasonable match. This type of tuning can utilize active tuning circuits. Active tuning circuits include active switching devices and can be complex and large because numerous switching devices and impedance elements may be required. The resultant size, power-consumption, and complexity may be unwanted in some applications (e.g., mobile devices). In mobile devices, passive tuning circuits may be used for matching. Passive tuning circuits do not require active switches. Instead a passive tuning circuit may include a tunable capacitor having a capacitance that can be adjusted (i.e., tuned) to match the antenna to the internal circuitry.

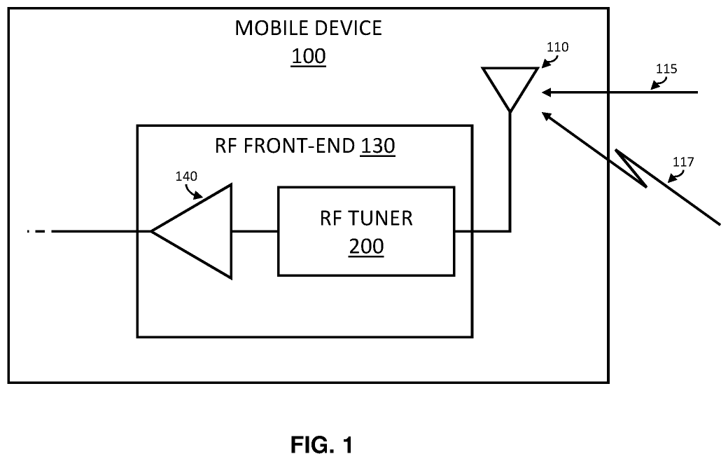

FIG. 1 illustrates a block diagram of a wireless mobile device (e.g., table, phone, etc.) according to a possible implementation of the present disclosure. The mobile device 100 includes an antenna 110 that can be configured to transmit and receive radio frequency signals (i.e., RF signals) for communication. FIG. 1 illustrates a receiving portion of an RF front-end 130. An RF signal 115 can be received at the RF front-end 130 via the antenna 110. The RF signal may be amplified by an amplifier 140 of the RF front-end 130. Reflections of the RF signal between the antenna and the amplifier can be minimized to ensure sensitivity and to prevent damage. The reflections can be minimized by matching an impedance of the antenna 110 to an impedance of the amplifier 140. Accordingly, the RF front-end 130 includes a radio frequency tuner (i.e., RF tuner 200) configured to match (i.e., tune) impedances. The environment of the mobile device 100 can change (i.e., load) the impedance of the antenna 110 (e.g., through capacitive coupling). As a result, the RF tuner 200 can be configured to tune changes in antenna impedance to maintain the matching.

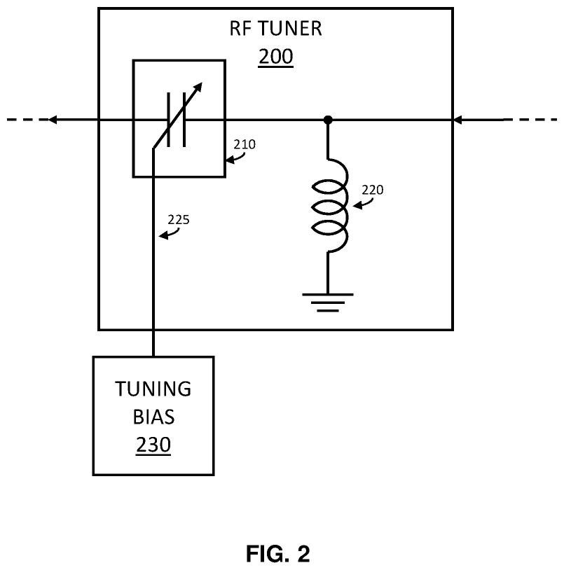

FIG. 2 illustrates a block diagram of an RF tuner 200 according to a possible implementation of the present disclosure. The RF tuner 200 can include one or more resistive and/or reactive (e.g., inductive, capacitive) elements. The one or more resistive/reactive elements can be arranged in various circuit topologies. The present disclosure is not limited to a particular topology. In the implementation shown, the RF tuner 200 includes an inductor 220 and a variable RF capacitor (i.e., variable capacitor 210).

The variable capacitor 210 (i.e., tunable capacitor, tuning condenser, varactor) can be configured to receive a tuning signal 225 from a tuning bias circuit 230 and change its capacitance in response to the tuning signal 225. The variable capacitor can be tuned using an analog tuning signal rather than using digital switching signals (i.e., for digitally switching a bank of capacitors). For example, an amplitude of the analog tuning signal (e.g., a voltage) can be changed (e.g., increased from zero) to change (e.g., reduce) the capacitance of the variable capacitor 210.

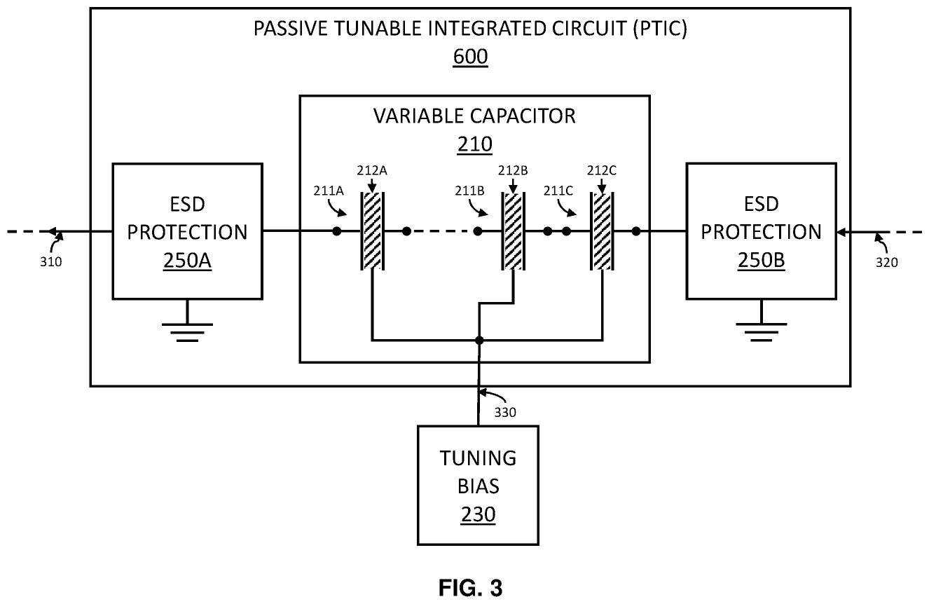

FIG. 3 schematically illustrates a block diagram of a variable capacitor according to an implementation of the present disclosure. The variable capacitor 210 may include a plurality of capacitors 211A, 211B, 211C coupled in series (or in parallel) with one another to produce an overall capacitance between an input 320 and an output 310 of the PTIC 600. The input 320 and the output 310 can be interchanged as the variable capacitor 210 may be operate similarly regardless of its connection orientation (i.e., bidirectional). Each of the plurality of capacitors 211A, 211B, 211C may have a tunable dielectric material 212A, 212B, 212C between two electrodes. An electrical signal may be generated by a tuning bias circuit (i.e., tuning bias circuit 230) and coupled to the tunable dielectric material (212A, 212B, 212C) via a DC control input 330 of the PTIC 600. The electrical signal can change a capacitance of each capacitor (211A, 211B, 211C), and the overall capacitance of the variable capacitor 210.

One insulating material that is low loss at RF frequencies and that has a tunable dielectric constant is Barium Strontium Titanate (BST). BST has a dielectric constant that depends on an applied electric field. Accordingly, a DC bias voltage (i.e., bias voltage) may be applied to a BST filled capacitor to set the dielectric constant, and the bias voltage may be changed (i.e., tuned) to change its capacitance. This type of tuning can be referred to as passive tuning because there is no active switching (e.g., using transistors) for tuning.

Barium Strontium Titanate may be used as the tunable dielectric material in a variable capacitor for RF frequencies (e.g., 2.5 Gigahertz (GHz)). BST has a field-dependent permittivity (i.e., dielectric constant) that can be changed with the application of a high voltage (e.g., 10-20 kilovolts (kV) per centimeter (cm)). While BST may have a high breakdown voltage (e.g., 1000 kV/cm), compared with other technologies (e.g., varactor diodes), BST may be still susceptible to breakdown when used in some variable capacitors.

A passive tunable integrated circuit (PTIC) is a BST capacitor that is fabricated as an integrated circuit using semiconductor process steps. Dimensions (e.g., distance (d)) of a PTIC may be very small, making it susceptible to damage from electro-static discharge (ESD). This is especially true when the PTIC is coupled to an antenna of wireless device (e.g., as an antenna tuning element) because the antenna of the wireless device is configured to easily couple energy into the wireless device.

A mobile device 100 (e.g., tablet, cellphone) may require very small variable capacitors for RF tuning of an RF front-end 130. To meet these requirements, a passive tunable integrated circuit 600 can be fabricated using photolithography and semiconductor processing to include small variable capacitors using BST. Further, the PTIC can be in a wafer level chip scale package to minimize packaging size.

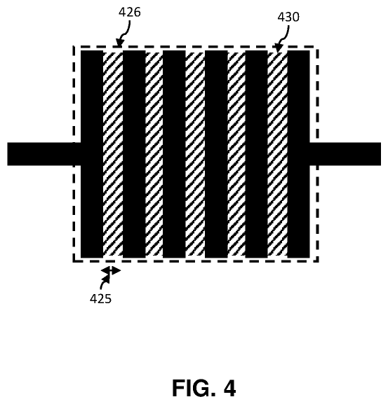

FIG. 4 illustrates a top view of a variable capacitor 210 having a curve-free topology suitable for a PTIC implementation according to a possible planar implementation. The variable capacitor includes a plurality of series-connected capacitors coupled between an input and an output. The series connection of the capacitors can divide a voltage to improve a linearity of each capacitor. The capacitors include a plurality of planar electrodes fabricated in a single layer metal process. The electrodes are substantially uncurved (i.e., straight) to efficiently fill an area 426 that is rectangular or square. A separation 425 between adjacent electrodes may be very small (e.g., 5 micrometers (μm)). As a result, a field strength, measured in volts per centimeter (V/cm), experienced by BST 430 filling the areas between the adjacent electrodes can be higher than the breakdown voltage of BST, especially in applications where high voltages are expected.

The variable capacitor 210 may also be implemented in a non-planar configuration. For example, a PTIC can be fabricated as follows. A conductive metal layer may be used as a bottom layer of a capacitor structure. Next, a first dielectric layer can be added to the bottom layer. Next, a second conductive layer can be added to the first dielectric layer. Next a second dielectric layer can be added to the second conductive layer. Finally, a top metal layer can be added to the second dielectric layer to serve as a top layer of the capacitor structure. Only the top metal layer is appropriate for using in connections and ESD structure. The separation between capacitor plates in the non-planar configuration can be very small because it is the dielectric thickness of the first and/or second dielectric layer. Further, the dielectric itself may be constituted by multiple layers of thinner dielectric (e.g., to improve dielectric leakage along dielectric crystalline boundaries as formed in some BST depositions).

Returning to FIG. 1, an RF front-end 130 of a mobile device 100 may electro-static discharge (ESD 117). A high-voltage signal form the electro-static discharge (ESD 117) can be easily coupled to the RF front-end 130 by the antenna 110, which is configured to efficiently transfer energy from a frequency band. For example, energy of an ESD signal may be high in a band that the antenna is tuned to (e.g., around 2.5 Gigahertz (GHz)). The ESD may be from a variety of sources and can be modeled variously. For example, the ESD 117 may result from a discharge from a human being, from a charged device, or from a machine (e.g., charged inductor). The ESD 117 can be modeled to determine a range of voltages and/or field strengths that could result. For example, the ESD may be modeled using a human body model (HBM), charged device model (CDM), and/or machine model (MM). ESD for from a human includes energy around a frequency of 2.5 GHz. When the antenna of the mobile device is tuned to a frequency around 2.5 GHz it can act as an ESD attractor (i.e., efficiently couples of ESD).

A BST variable capacitor can be sensitive to current pulse discharges such as HBM and MM type discharges. These ESDs can cause a high field strength in the dielectric because the electrode to electrode (i.e. plate to plate) separation of the capacitor can be small (e.g., 5 μm). These field strengths can exceed the breakdown of the BST and a current plasma that results can cause conductor migration through the BST and, ultimately, failure of the capacitor. In a passive capacitor structure (i.e., a BST variable capacitor) there are no active devices (e.g., switching devices) available for ESD protection.

Returning to FIG. 3, the signal created by the ESD 117 may create a field strength (e.g., >10,000 V/cm) in one or more of the capacitors 211A, 211B, 211C that is sufficient to cause the tunable dielectric material 212A, 212B, 212C (i.e., BST) to breakdown. The breakdown can damage the RF tuner 200 so that tuning is affected. Additionally, the breakdown couples the ESD signal from an input 320 to an output 310 of the PTIC. As a result, the signal from the ESD 117 can also damage one or more circuits coupled to the RF tuner (e.g., the amplifier 140). Accordingly, the PTIC 600 can include ESD protection circuits 250A, 250B. An ESD protection circuit at the input 320 (i.e., input ESD protection circuit 250B) can prevent the tunable dielectric material 212A, 212B, 212C (i.e., BST) in the one or more of the capacitors 211A, 211B, 211C from breaking down, while an ESD protection circuit at the output 310 (i.e., output ESD protection circuit 250A) can protect subsequent circuitry from receiving a high voltage signal coupled through the breakdown of one or more of the capacitors 211A, 211B, 211C. The present disclosure is not limited to the implementation including both the input and output ESD protection circuits 250A, 250B. In another possible implementation, the PTIC may include an input electro-static discharge protection circuit (i.e., input ESD protection circuit 250B) but no output electro-static discharge protection circuit (i.e., output ESD protection circuit 250A) (and vice versa). The ESD protection circuit may include one or more spark gaps.

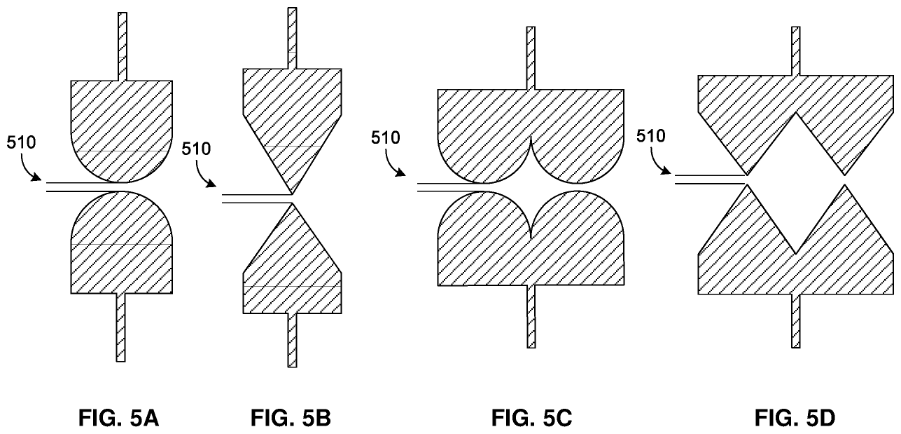

FIGS. 5A-5D illustrates four possible implementations of ESD protection circuit according to an implementation of the present disclosure. The ESD protection circuit can include at least one spark gap. Each spark gap is characterized by two electrodes separated (at their closest separation) by a gap. A plasma may be formed to conduct current through the gap when a voltage at the gap meets or exceeds a breakdown voltage for a given atmospheric pressure. For example, a standard breakdown voltage for air at 1 atmosphere (atm) is approximately three volts per micron (i.e., 3 V/μm).

An ESD protection circuit can be designed to provide a conduction path to ground when a voltage is applied to an input of the ESD protection circuit that exceeds a trigger field strength. The conduction path may provide for a period to conduct current at a current level sufficient to discharge an ESD. Design parameters of a spark gap may be selected to provide this function.

A first spark gap design parameter may be a planar electrode configuration in which a first electrode of a spark gap is in a plane with a second electrode of the spark gap. This configuration may be desirable for its compliance with existing PTIC fabrication processes. The ESD protection circuits shown in FIGS. 5A-5D can be fabricated using a single layer metal process, such as used by the capacitor (see FIG. 4).

A second spark gap design parameter may be a gap width 510 of the spark gap. The gap witch (i.e., gap) can be selected so that a spark gap conducts at a higher or lower breakdown voltage (i.e., larger or smaller gap). The atmospheric breakdown (e.g., 4V/μm), which is a function of atmospheric properties, can be used to design the gap width to achieve the desired breakdown to protect the PTIC 610.

A third spark gap design parameter may be the shape of the electrodes. Circular electrodes (FIGS. 5A, 5c) may provide a lower field strength in the gap width than triangular electrodes (FIGS. 5B, 5D). Additionally, the circuit electrodes may reduce a parasitic capacitance associated with the spark gaps. Accordingly, the shape of the electrode may be selected to adjust a trigger field strength of an ESD protection circuit.

A fourth spark gap design parameter may be a number of spark gaps in parallel (or in series). Multiple parallel spark gaps (FIGS. 5C, 5D) may carry more current than single spark gaps (FIGS. 5A, 5B). Accordingly, a number of parallel spark gaps may be selected to adjust a current level of an ESD protection circuit.

A fifth spark gap design parameter may be a material to cover the spark gap and electrodes. A breakdown of a spark gap can be raised by coating the gap width with a layer (i.e., overcoat). For example, a planar spark gap fabricated with existing PTIC fabrication processes may include as a glass dielectric layer added to the electrodes for passivation. It may be desirable to remove, this coating layer to reduce a trigger field strength of an ESD protection circuit. In some implementations, an etch process of the PTIC fabrication may be used for this removal.

In an example, an RF tuner 200 includes a variable capacitor that has a DC voltage rating of 20 volts in order to handle signals associated with the mobile device 100. The variable capacitor for the mobile device is a PTIC with a plurality of capacitors filled with BST. To keep the dimensions of the PTIC small, each of the plurality of capacitors has straight plates (i.e., electrodes) so that the polarity of capacitors can fill a square or rectangular area. In other words, the capacitors may not include curved electrodes, which could offer some ESD protection. Instead, the plurality of capacitors may include a curve-free topology, such as shown in the capacitor implementation of FIG. 4. A voltage across each capacitor should be kept below the DC voltage rating for safe operation. Accordingly, the PTIC includes an ESD protection circuit configured to route a signal of 20 volts to ground before it reaches the capacitors. As mentioned previously, a spark gap, such as shown in FIGS. 5A-5D, can breakdown (i.e., be triggered) at a field strength of about 4 Vim if a glass dielectric does not cover the structure. Thus, the capacitors should have a gap width of about five microns (5 μm) because (5 μm)×(4V/μm)=20V. Gap widths of this size may only be possible to fabricate using semiconductor processes but may not be possible to fabricate using printed circuit board (PCB) processes. Additionally, gap width of this size may require removal of a glass dielectric over the spark gap to lower the trigger field strength from about 10 V/μm to about 4 V/μm.

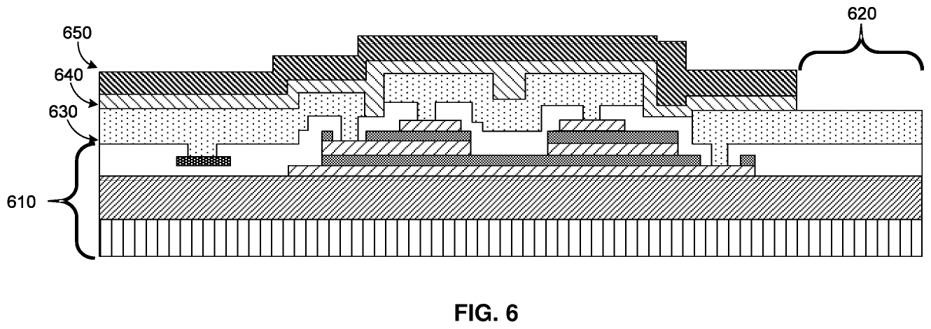

FIG. 6 is a cross section view of a PTIC of a portion of spark gap. After the PTIC 610 is fabricated a first metal layer 630 for interconnection is deposited, patterned, and etched. Next, an overcoat that includes a barrier layer 640 and a nitride layer 650 is deposited over the first metal layer 630. To expose an electrode of the spark gap (i.e., to reduce its trigger field strength), the overcoat (i.e., barrier layer 640 and nitride layer 650) is etched to expose the electrode of the spark gap 620. This process can also be used to create pads in the PTIC, so no additional process is necessary. Accordingly, adding ESD protection to the PTIC can be cost efficient.

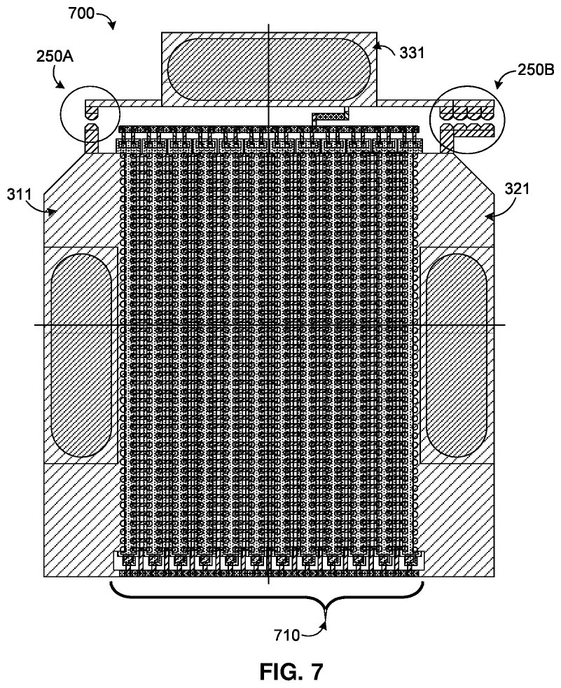

FIG. 7 is a top view of a PTIC 700 according to a possible implementation of the present disclosure. The first metal layer of the PTIC includes an input electrode 321 coupled to an input 320 of the PTIC and an output electrode 311 coupled to an output 310 of the PTIC. The electrodes are coupled to a plurality of series-connected capacitors (i.e., capacitor array 710). BST is deposited between adjacent electrodes in the capacitor array 710. A bias signal may be applied to a control electrode coupled to a DC control input 330 of the PTIC to tune the BST dielectric constant (i.e., relative permittivity). The DC control input 330 may appear as a ground for RF signals (i.e., a radio-frequency ground). The PTIC 700 includes an input ESD protection circuit 250B and an output ESD protection circuit 250A. The input ESD protection circuit includes at least one spark gap between an input electrode 321 and a radio-frequency ground electrode (RF ground electrode 331). In the implementation shown, the input ESD protection circuit 250B includes four parallel spark gaps, each having electrodes with a circular shape. The output ESD protection circuit 250A includes at least one spark gap between an output electrode 311 and an RF ground electrode 331. In the implementation shown, the output ESD protection circuit 250A includes one spark gap having electrodes with a circular shape. The electrodes for the spark gaps can be planar because the input electrode 321, the output electrode 311, and the RF ground electrode 331 can be fabricated on the same metal layer (e.g., the first metal layer). In the implementation shown, the electrodes of the spark gaps of the input and output ESD protection circuits are included in the first metal layer of the PTIC.

The capacitor array includes a stack of series-connected capacitors. In one possible implementation, the target capacitance required for a variable capacitor in a mobile application may be approximately 2.7 pico farads (pF). If the target capacitance is 2.7 pF then the effective capacitance of each capacitor in a stack of 32 capacitors is about a 32\hat{ }2×2.7 pF=2.7 nano farads (nF). The area for the stack in a PTIC can be very small. For example, less than 0.6 square millimeters (mm²) may be provided for the capacitor array (i.e., stack). This small area leads to a capacitance density of 4.6 nF/mm². The small dimensions of the PTIC and the high capacitor density can make alternative methods to mitigate ESD breakdown difficult. For example, there is not enough area in a PTIC to use geometric optimization (i.e., removal of corners or high field areas) to improve (i.e., increase) a breakdown voltage of each capacitor. The spark gap ESD protection with top passivation removed achieves all the goals of ESD protection without changing the size of the PTIC and without changing the fabrication process of the PTIC.

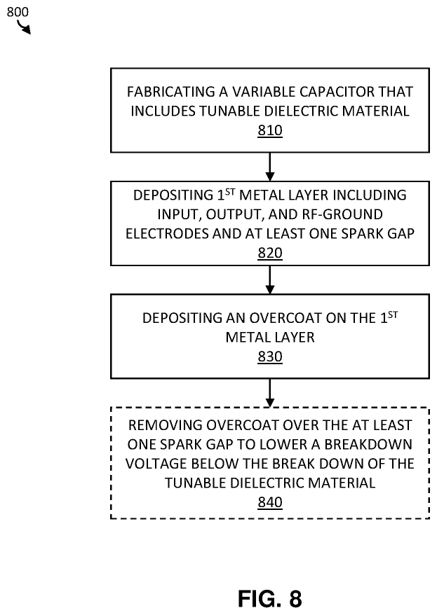

FIG. 8 is a flowchart of a method to protect a PTIC from an ESD. In the method 800, a variable capacitor is fabricated 810 using semiconductor processes. The variable capacitor can include an array of capacitors between an input electrode and an output electrode. Each capacitor in the array of capacitors can each have a tunable dielectric material (e.g., BST) that is coupled to a DC voltage source (i.e., bias source) that appears as a ground to RF signals, such as the ESD. The method further includes depositing a first metal layer that includes (i.e., defines) an input electrode, and output electrode, and an RF-ground electrode. The first metal layer also includes (i.e., defines) at least one spark gap. The method further includes depositing 830 of an overcoat (e.g., for passivation) on the first metal layer and removing 840 the overcoat from the at least one spark gap. The removal of the overcoat can lower a break down voltage of the at least one spark gap to a voltage that is below a breakdown voltage of the tunable dielectric material. When triggered the at least one spark gap, the at least one spark gap can route potentially damaging signals (e.g., from ESD) the RF ground electrode before damaging the variable capacitor or circuits coupled to the variable capacitor.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC), Aluminum Nitride (AlN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A passive tunable integrated circuit, comprising:
a variable capacitor, including a capacitor array coupled between an input electrode and an output electrode, at least one capacitor in the capacitor array having a tunable dielectric coupled to a radio-frequency ground electrode; and
an input electro-static discharge protection circuit coupled between the input electrode and the radio-frequency ground electrode, the input electro-static discharge protection circuit including at least one spark gap.

2. The passive tunable integrated circuit according to claim 1, wherein the variable capacitor is a radio frequency (RF) capacitor.

3. The passive tunable integrated circuit according to claim 1, wherein the capacitor array includes a plurality of series-connected capacitors.

4. The passive tunable integrated circuit according to claim 3, wherein the plurality of series-connected capacitors has a curve-free topology.

5. The passive tunable integrated circuit according to claim 1, further comprising:
an output electro-static discharge protection circuit coupled between the output electrode and the radio-frequency ground electrode, the output electro-static discharge protection circuit including at least one spark gap.

6. The passive tunable integrated circuit according to claim 5, wherein:
the at least one spark gap of the input electro-static discharge protection circuit is planar and on a first metal layer; and
the at least one spark gap of the output electro-static discharge protection circuit is planar and on the first metal layer.

7. The passive tunable integrated circuit according to claim 1, wherein the input electrode, the output electrode, the radio-frequency ground electrode, and the at least one spark gap are on a first metal layer.

8. The passive tunable integrated circuit according to claim 1, wherein the at least one spark gap includes circular electrodes.

9. The passive tunable integrated circuit according to claim 1, wherein the at least one spark gap includes triangular electrodes.

10. The passive tunable integrated circuit according to claim 1, wherein the at least one spark gap includes electrodes that are exposed to reduce a trigger field strength.

11. The passive tunable integrated circuit according to claim 1, wherein the tunable dielectric is Barium Strontium Titanate (BST).

12. A radio frequency tuner for a mobile device, the radio frequency tuner comprising:
a passive tunable integrated circuit including:
an input electro-static discharge protection circuit coupled between an input electrode and a radio-frequency ground electrode, the input electro-static discharge protection circuit including at least one spark gap configured to couple an electro-static discharge above a trigger field strength to the radio-frequency ground electrode.

13. The radio frequency tuner for a mobile according to claim 12, wherein the electro-static discharge is a radio frequency signal from an antenna of the mobile device.

14. The radio frequency tuner for a mobile device according to claim 12, wherein the trigger field strength is less than a break down voltage of tunable dielectric material used in a variable capacitor of the passive tunable integrated circuit.

15. The radio frequency tuner for a mobile device according to claim 14, wherein the tunable dielectric material is Barium Strontium Titanate.

16. The radio frequency tuner for a mobile device according to claim 14, wherein the variable capacitor includes a plurality of series-connected capacitors arranged according to curve-free topology.

17. The radio frequency tuner for a mobile device, according to claim 12, wherein the passive tunable integrated circuit further includes:
an output electro-static discharge protection circuit coupled between an output electrode and the radio-frequency ground electrode, the output electro-static discharge protection circuit including at least one spark gap configured to couple the electro-static discharge above the trigger field strength to the radio-frequency ground electrode.

18. The radio frequency tuner for a mobile device according to claim 12, wherein the passive tunable integrated circuit is in a wafer level chip scale package.

19. A method to protect a passive tunable integrated circuit from an electro-static discharge, the method comprising:
fabricating a variable capacitor that includes a tunable dielectric material;
depositing a first metal layer on the variable capacitor, the first metal layer defining an input electrode, an output electrode, a radio-frequency ground electrode, and at least one spark gap coupled between the input electrode and the radio-frequency ground electrode; and
depositing an overcoat on at least a portion of the first metal layer, wherein the at least one spark gap of the first metal layer has no overcoat to lower a breakdown voltage of the at least one spark gap to below a breakdown voltage of the variable capacitor so that an electro-static discharge having a voltage that can damage the variable capacitor is routed to the radio-frequency ground electrode.

20. The method to protect a passive tunable integrated circuit according to claim 19, further comprising:
removing the overcoat from the at least one spark gap to lower a breakdown voltage of the at least one spark gap to below a breakdown voltage of the variable capacitor so that an electro-static discharge having a voltage that can damage the variable capacitor is routed to the radio-frequency ground electrode.

21. The method according to claim 19, wherein the tunable dielectric material is Barium Strontium Titanate.
